(19) United States
(12) Patent Application Publication
(10) Pub. No.: US 2026/0005721 A1
(43) Pub. Date: Jan. 1, 2026

(54) PERFORMANCE TRANSCEIVER

(71) Applicant: Intel Corporation, Santa Clara, CA (US)

(72) Inventors: Seng Siong Lee, Puchong (MY); Huey Koon Tee, Bayan Lepas (MY); Zechariah Balan, Kajang (MY); Pravinah Nair Shasidharan, Pravinah Nair (MY)

(21) Appl. No.: 18/754,502

(22) Filed: Jun. 26, 2024

(51) Int. Cl. H04B 1/44; H03K 3/017; H03K 3/037; H04B 17/21; H04B 17/345

(52) U.S. Cl. CPC H04B 1/44; H03K 3/017; H03K 3/037; H04B 17/22; H04B 17/345

(57) ABSTRACT

A receiver circuit is coupled to the transmitter circuit via one or more communication channels. The receiver circuit includes a first receive (Rx) driver circuit to generate a first received signal based on a first output signal. The receiver circuit includes a first calibration circuit to generate a first calibration signal based on an amplitude of the first output signal, and a second calibration circuit to generate a second calibration signal based on duty cycle distortion (DCD) associated with the first received signal. A multiplexer circuit coupled to the first calibration circuit and the second calibration circuit generates receiver calibration signals based on the first and second calibration signals. A finite state machine (FSM) circuit generates one or more activation signals based on the receiver calibration signals to configure the first Rx driver circuit.

### BACKGROUND

The ever-growing demand for improved data communications has driven the development of efficient transceiver solutions. However, configuring transceiver systems that comply with tight tolerance requirements, reduced electrical over-stress (EOS) violations, optimal signal integrity (SI) across corners, optimal timing margin, and reduced calibration costs remain challenging.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a graph illustrating a power consumption comparison between calibration methods across process corners and channel length, in accordance with some embodiments.

FIG. 2 is a block diagram of a transceiver system using cross-die calibration, in accordance with some embodiments.

FIG. 3A illustrates a transceiver resistor network transformation, in accordance with some embodiments.

FIG. 3B illustrates a graph of receive (Rx) input signal slope and amplitude changes with transmit (Tx) output impedance adjustment, in accordance with some embodiments.

FIG. 4 illustrates a graph of power consumption and slope comparison between prior techniques and the disclosed techniques across channel length, in accordance with some embodiments.

FIG. 5 is a block diagram of a transceiver system without receiver calibration circuits, in accordance with some embodiments.

FIG. 6A illustrates a transceiver system with a highlighted communication path used during amplitude and slope calibration, in accordance with some embodiments.

FIG. 6B illustrates a transceiver system with a highlighted communication path used during duty cycle (DC)-based calibration, in accordance with some embodiments.

FIG. 7A is a flow diagram of an example method for performing amplitude and slope calibration, in accordance with some embodiments.

FIG. 7B is a flow diagram of an example method for performing DC-based calibration, in accordance with some embodiments.

FIG. 8 illustrates duty cycle adjustment of a waveform, in accordance with some embodiments.

FIG. 9A is a graph of performance across data rates in accordance with some embodiments.

FIG. 9B is a graph of performance across channel length at 8 Gbps, in accordance with some embodiments.

FIG. 9C is a graph of performance with Vref settings at 8 Gbps, in accordance with some embodiments.

FIG. 9D is a graph of performance across process corners at 8 Gbps, in accordance with some embodiments.

FIG. 10 is a graph of amplitude and slope proportional to the VCC ratio with 50 Ohms termination, in accordance with some embodiments.

FIG. 11 is a graph of simulation results of amplitude and slope calibration, in accordance with some embodiments.

FIG. 12 is a graph of simulation results of DC-based calibration, in accordance with some embodiments.

FIG. 13A is a graph of simulation results for spatial transmit impedance mismatch with input/output (IO) distance, in accordance with some embodiments.

FIG. 13B is a block diagram of a floorplan for matching between clock IO and data IOs, in accordance with some embodiments.

FIG. 14 is a flow diagram of an example method for performing receiver calibration, in accordance with some embodiments; and

FIG. 15 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

As used herein, the term “AIB” indicates an advanced interface bus. As used herein, the term “BER” indicates bit error rate. As used herein, the term “Cal 1” indicates amplitude and slope calibration. As used herein, the term “Cal 2” indicates duty cycle calibration. As used herein, the term “DC” indicates duty cycle. As used herein, the term “DCD” indicates duty cycle distortion. As used herein, the term “DDR” indicates double data rate. As used herein, the term “EOS” indicates electrical overstress. As used herein, the term “FSM” indicates a finite state machine. As used herein, the term “IO” indicates input/output. As used herein, the term “IREM” indicates infrared emission microscopy. As used herein, the term “PCIe” indicates Peripheral Component Interconnect Express. As used herein, the term “PPA” indicates power, performance, and area. As used herein, the term “R-C” indicates resistance and capacitance. As used herein, the term “Rx” indicates receiver (or receive). As used herein, the term “SI” indicates signal integrity. As used herein, the term “TFR” indicates a thin-film resistor. As used herein, the term “Tx” indicates transmitter (or transmit). As used herein, the term “TRX” indicates transceiver. As used herein, the term “UCle” indicates Universal Chiplet Interconnect Express. As used herein, the term “Vref” indicates reference voltage.

In some aspects, the disclosed techniques can be used to improve the following drawbacks associated with existing transceiver technologies:
(a) Constant impedance requirement. Tight tolerance requirement for transmitter (Tx) (e.g., 30 Ohms +/−10%) and receiver (Rx) (e.g., 50 Ohms +/−10%) for UCle standard specification can result in worsening of PPA. Constant impedance is not an efficient method because it does not directly control the outcomes, which are constant amplitude, constant slope, and minimizing overshoot. Moreover, the UCle standard die-to-die transceiver has a short channel length (e.g., less than 25 mm), which may not use strict impedance matching.
(b) Electrical over-stress (EOS) violation. For a full-swing non-terminated Rx use case, the EOS can be violated at the fast corner.
(c) Poor eye opening (e.g., due to reduced SI across corners).
(d) Poor timing margin. Reduced timing margin at the Rx flop due to DCD for cross-corners (e.g., fast NMOS and slow PMOS, and vice versa).
(e) High test cost. Impedance calibration may be performed using a precision reference resistor, which can increase manufacturing costs.

In some aspects, TRX systems can be based on the following configurations:
(a) Better tolerance with large devices. Using larger devices can tighten the impedance tolerance by reducing device mismatch (which can be the most significant error contributor). However, this configuration can worsen the PPA because larger devices can result in proportionally larger parasitic capacitances, which degrade the performance (larger R-C constant) and power (larger capacitance to charge/discharge).
(b) Slowing down signals. In some aspects, EOS can be reduced by slowing the Tx driver signal slope at the fast corner, but this results in a poorer eye opening at the slow corner, which constrains the design trade-off.
(c) Designing for worst-case corner. Overdesign for the slowest corner with lower Tx and Rx impedance can increase the eye opening. However, this configuration can incur higher power for all other corners because the impedance does not scale with corners for the constant impedance method.
(d) DCD compensation. In some aspects, DCD can be improved by compensating via buffer slope for the series connected buffer chain. However, this technique may not be capable of achieving a DCD smaller than 1%.
(e) Constant impedance calibrator. In some aspects, a precision reference resistor can be used to perform constant impedance calibration. Two methods to obtain precision reference resistor are using a precision external resistor (this can increase the bill of material (BOM) cost and board area) and calibrating the internal TFR reference resistor to reduce its tolerance (this can increase the test time and as a result, higher test cost).

In some aspects, the disclosed techniques can be used to regulate the signal amplitude, slope, overshoot, and DC at the Rx to maximize the eye-opening signal characteristic, achieve optimal SI, and prevent EOS conditions across all corners. The disclosed techniques can be based on sensing the full channel characteristics of the TRX (e.g., Tx, Rx, and channel) and then dynamically adjusting the Tx output impedance to achieve a fixed resistance-capacitance (RC) constant at the Rx input. In some aspects, a programmable reference voltage (Vref) can be used to control the desired signal regulation level, thus avoiding an expensive precision reference resistor or tester time. In some aspects, an integrated DC calibrator can be added to ensure symmetrical rise and fall time to increase the Rx timing margin. The PPA can be improved as the proposed techniques avoid overdesign of existing techniques.

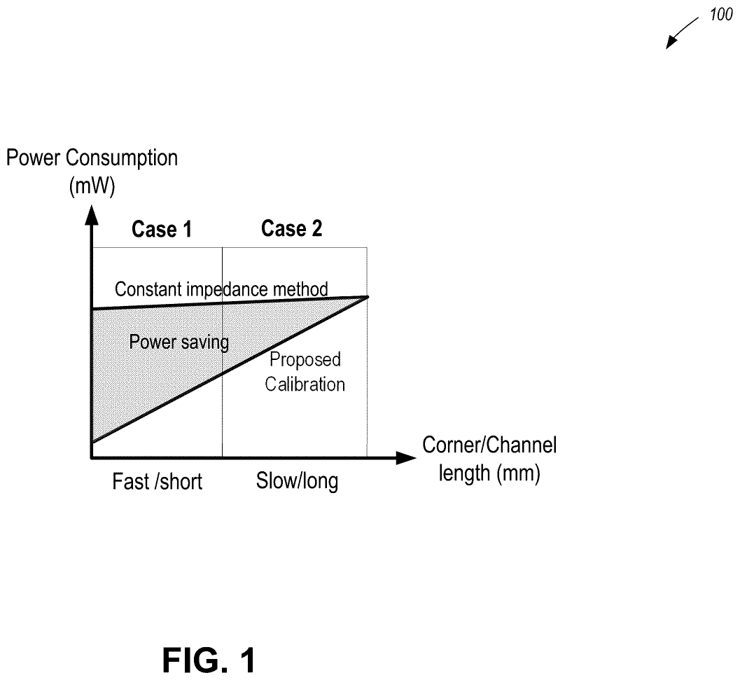

FIG. 1 is a graph 100 illustrating a power consumption comparison between calibration methods across process corners and channel length, in accordance with some embodiments.

The disclosed TRX architecture (including Rx-based calibration techniques) can be associated with the following advantages over existing TRX architectures:
(a) Optimal impedance for consistent performance. The dynamic calibrator senses the full TRX chain conditions and selects an optimal Tx impedance to compensate for any condition changes in the TRX chain by targeting constant R-C product rather than constant R (as done in existing techniques). The outcomes are constant signal amplitude and slope, resulting in optimal eye-opening, SI, and preventing EOS conditions. The disclosed TRX architecture achieves improved PPA compared to existing architectures and ease of design due to its adaptability to system conditions (e.g., channel length, device corners, and data rate).
(b) Increase timing margin. DCD calibration is integrated to guarantee optimal DCD (e.g., DCD <1%), which increases the timing margin at the Rx timing flop to ease timing closure. In this regard, the disclosed TRX architecture achieves improved PPA and reduced engineering costs.
(c) Zero test cost. The dynamic calibrator in the disclosed TRX architecture uses programmable Vref, which is freely available on-die (e.g., bandgap reference voltage or supply voltage). In this regard, the disclosed TRX architecture avoids the need for an internal/external precision reference resistor, which is costly.

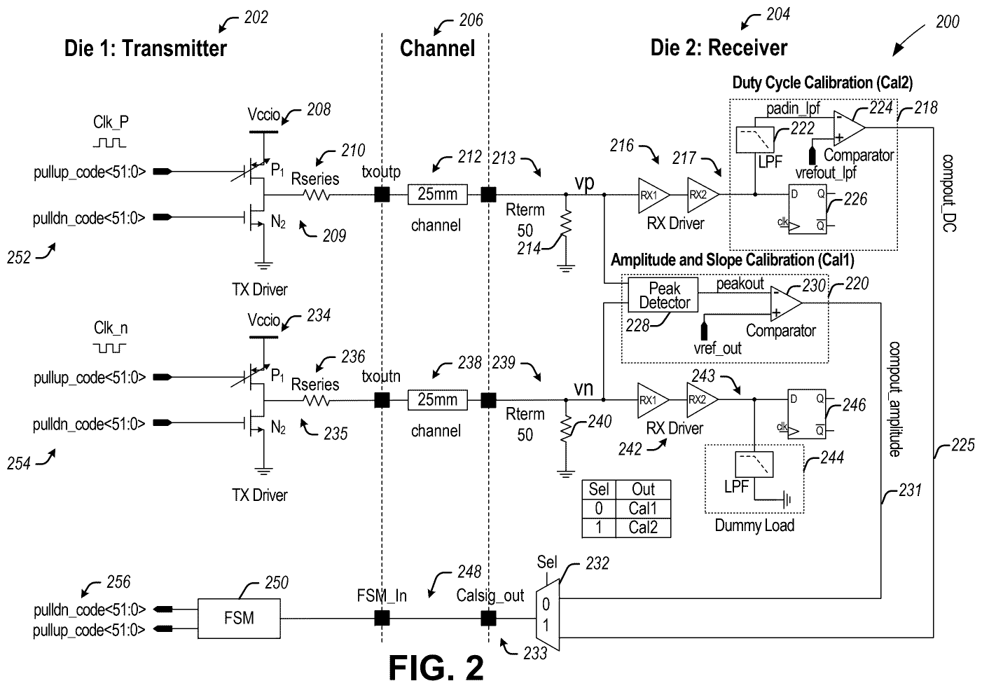

FIG. 2 is a block diagram of a transceiver (TRX) system 200 using cross-die calibration, in accordance with some embodiments. Referring to FIG. 2, the TRX system 200 includes a transmitter 202 (also referred to as Tx 202), a receiver 204 (also referred to as Rx 204), and one or more channels 206 coupling the Tx 202 and the Rx 204. As used herein, the term “cross-die calibration” indicates calibration performed between two or more dies.

In some aspects, Tx 202 includes a first Tx driver circuit 208 and a second Tx driver circuit 234. Each of the Tx driver circuits can include a pull-up transistor (e.g., PMOS transistor P1) and a pull-down transistor (e.g., NMOS transistor N2).

The first Tx driver circuit 208 communicates a first output signal 209 to Rx 204 via resistor 210, communication channel 212, and termination resistor 214. The first output signal received at the Rx 204 side can be referred to as the first output signal 213.

The second Tx driver circuit 234 communicates a second output signal 235 to Rx 204 via resistor 236, communication channel 238, and termination resistor 240. The second output signal received at the Rx 204 side can be referred to as the second output signal 239. In some aspects, resistors 210 and 236 are thin-film resistors (TFRs).

The first Tx driver circuit 208 can be configured based on activation signals 252, and the second Tx driver circuit 234 can be configured based on activation signals 254. In some aspects, activation signals 252 and 254 can include one or more pull-up codes and one or more pull-down codes, which can be used to activate (or deactivate) corresponding pull-up links (e.g., pull-up transistors) and pull-down links (e.g., pull-down transistors) of the first Tx driver circuit 208 and the second Tx driver circuit 234.

In some aspects, Tx 202 includes a finite state machine (FSM) circuit 250 configured to generate activation signals 256 based on receiver calibration signals 233 received from the multiplexer circuit 232 via communication channel 248. In some aspects, activation signals 252 and 254 are the same as activation signals 256.

The Rx 204 includes a first calibration circuit 220 (also referred to as Cal 1), a second calibration circuit 218 (also referred to as Cal 2), Rx driver circuits 216 and 242, a flip-flop circuit 246, a dummy load 244, and a multiplexer circuit 232.

The first calibration circuit 220 can include a peak detector circuit 228 and a comparator circuit 230. The second calibration circuit 218 can include a DCD detector circuit 222, a flip-flop circuit 226, and a comparator circuit 224. In some aspects, the DCD detector circuit 222 can be a low-pass filter (LPF) (also referred to as LPF 222).

In operation, the Rx driver circuit 216 generates a first received signal 217 based on the first output signal 213. The Rx driver circuit generates a second received signal 243 based on the second output signal 239.

The peak detector circuit 228 of the first calibration circuit 220 generates a peak output signal (e.g., peakout) based on the amplitude of the first output signal 213 and the amplitude of the second output signal 239. The comparator circuit 230 generates a first calibration signal 231 based on the peak output signal and a reference voltage signal (e.g., Vref_out), which can be based on a desired amplitude/slope for the signals received by the Rx 204 via the one or more communication channels 206.

The DCD detector circuit 222 generates a DCD signal (padin_lpf) based on the first received signal 217. The DCD signal is indicative of the DCD associated with the first received signal 217. The comparator circuit 224 generates a second calibration signal 235 based on the DCD signal and a reference voltage signal (e.g., Vrefout_lpf). In some aspects, Vrefout_Ipf is one-half of the supply voltage of the Rx 204.

The first calibration signal 231 and the second calibration signal 225 are communicated to multiplexer circuit 232. The multiplexer circuit 232 outputs the first calibration signal 231 and the second calibration signal 225 as Rx calibration signals 233.

In some aspects, FSM circuit 250 generates one or more pull-up codes and one or more pull-down codes as the activation signals 256 (which are the same as activation signals 252 and 254) based on the first calibration signal 231. The number of pull-up links of the first Tx driver circuit 208 (and/or the second Tx driver circuit 234) is adjusted based on the one or more pull-up codes. In some aspects, the number of pull-down links of the first Tx driver circuit 208 (and/or the second Tx driver circuit 234) is adjusted based on the one or more pull-down codes.

In some aspects, FSM circuit 250 generates one or more additional pull-down codes (which can be part of activation signals 256) based on the second calibration signal 225. The number of pull-down links of the first Tx driver circuit 208 (and/or the second Tx driver circuit 234) is adjusted further based on the one or more additional pull-down codes.

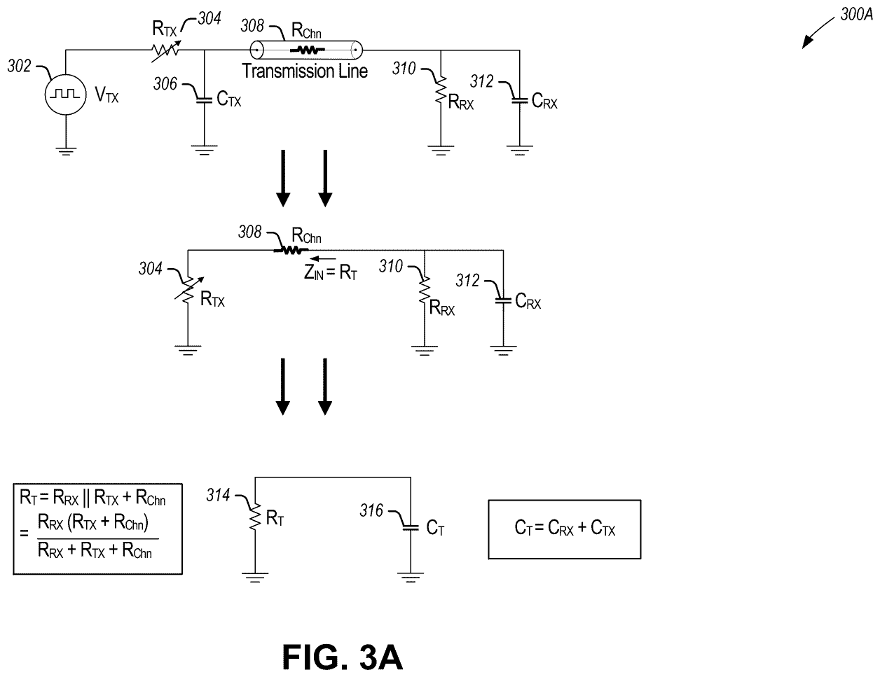

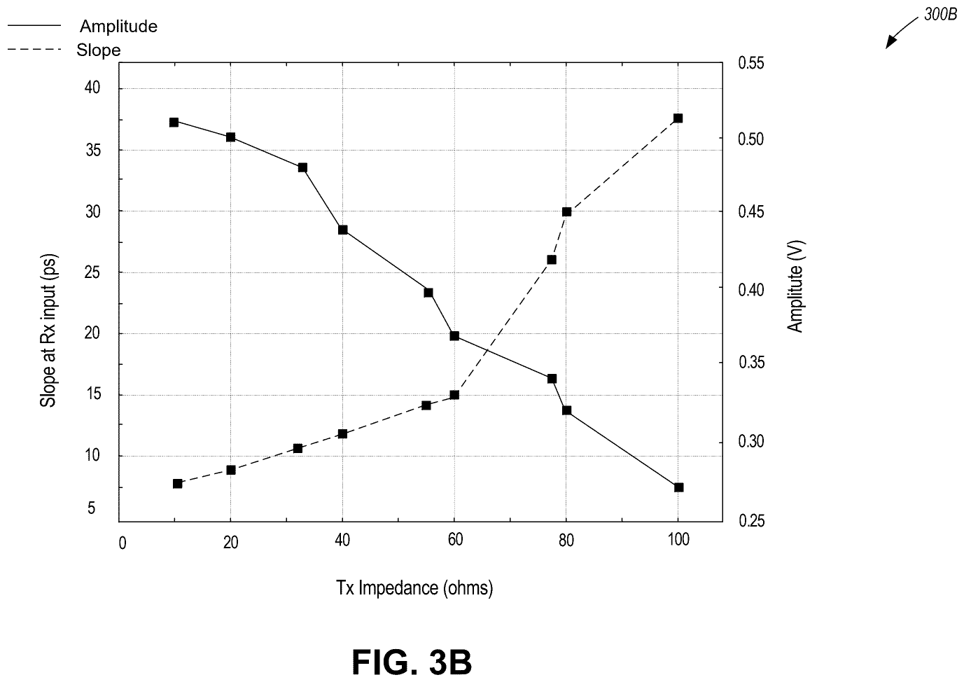

An additional description of aspects associated with the TRX system 200 is provided in connection with FIG. 3A-FIG. 7B.

To ensure optimal SI and wide eye opening for a high-speed TRX when driving a capacitive load, the disclosed techniques can be based on maintaining a low Tx output impedance. This is because the R-C time constant can be kept below the maximum data rate to prevent signal distortion, which degrades SI and results in eye closing. In some aspects, the TX output impedance and the RX input impedance can be calibrated to achieve a constant low impedance target. However, the constant impedance method may not be efficient for improving SI because load conditions vary due to process, voltage, and temperature (PVT) variation, resulting in a high RC constant at the worst-case condition. The disclosed techniques can be based on designing with minimum Tx and Rx impedance for the worst-case condition, but it can lead to overdesign, which may result in higher power consumption, larger areas, and low-performance metrics (e.g., poor PPA) due to large device parasitic capacitance.

In the context of die-to-die or chipset IOs such as UCle and AIB, the distance between the dies is relatively short, especially when compared to traditional wireline transmissions such as PCIe and DDR standards. For the UCle open standard, the die-to-die channel length can be below 25 mm. Due to the short distance, even at a data rate of 16 Gbps, maintaining strict impedance matching may not be mandatory because the signal slew rate is still relatively low compared to the channel length for minimizing signal reflections. However, optimal SI can be maintained by keeping the R-C constant below the maximum data rate. To achieve a low Bit Error Rate (BER), the TX signal can have sufficiently large amplitude to produce eye-opening wide enough for the Rx to accurately detect the symbols from the received signal.

FIG. 3A illustrates diagram 300A of a transceiver resistor network transformation, in accordance with some embodiments. Referring to FIG. 3A, the transceiver resistor network includes a voltage source 302, Tx resistance 304, Tx capacitance 306, transmission line resistance 308, Rx resistance 310, and Rx capacitance 312. This resistor network can be transformed into a resistor network that includes Tx resistance 304, transmission line resistance 308, Rx resistance 310, and Rx capacitance 312. The final transformation of the resistor network can be represented by total resistance 314 (RT) and total capacitance 316 (CT), with corresponding equations listed in FIG. 3A.

FIG. 3B illustrates graph 300B of receive (Rx) input signal slope and amplitude changes with transmit (Tx) output impedance adjustment, in accordance with some embodiments.

In some aspects, impedance termination at the input of the RX can be performed to configure the following functionalities:
(a) to reduce the high signal slew rate requirement at a high data rate by reducing the signal amplitude through the voltage divider effect created by the Tx output impedance in conjunction with the Rx input impedance.
(b) to decrease the total impedance seen at the Rx input due to parallel impedance combination [(TX output impedance, RTX+Channel resistance, RChn)//RX input impedance, RRX]. This ensures that the total R-C time constant remains below the data rate of the TRX, as depicted in FIG. 3A.

The UCle open standard specification states that a 50 Ohms Rx input termination is recommended for data rates greater than 8 Gbps. FIG. 3A illustrates the conceptual diagram of the impedance transformation of the TRX network, which results in the amplitude and slope of the signal received at the RX. The total resistance (RT) and capacitance (CT) at the Rx input determine the R-C constant, which is associated with SI. Based on the equation provided in FIG. 3A, if the Rx load impedance deviates from 50 Ohms in the terminated case, the new Tx impedance can be calculated to maintain SI. For a typical UCle application, when the Tx impedance (Rtx) is 30 Ohms, the channel resistance (RChn) is 5 Ohms, and the Rx impedance (Rrx) is 50 Ohms, the total equivalent RT is calculated to be 19.3 Ohms. Below are two examples demonstrating how the TX impedance can be dynamically adjusted to maintain RC-constant.
Case 1: To maintain RT at 19.3 Ohms, considering a channel loss of 5 Ohms, the Tx impedance can be adjusted to 80 Ohms when the Rx impedance is reduced to 25 Ohms.
Case 2: To maintain RT at 19.3 Ohms, considering a channel loss of 5 Ohms, the Tx impedance can be adjusted to 21 Ohms when the Rx impedance is increased to 75 Ohms.
Cases 1 and 2 demonstrate the adaptive nature of the proposed calibration, which actively adjusts the Tx output impedance to counteract any changes in the Rx input impedance, ensuring consistent signal amplitude.

Furthermore, the proposed techniques preserve the signal slope using dynamic Tx impedance adjustment despite variations in TRX resistance (R) or capacitance (C). For the unterminated case, the Tx impedance is used to control the signal slope only. The simulation results in FIG. 3B show the enhancements in signal slope and amplitude for the terminated case when the Tx output impedance is reduced from 100 Ohms to 10 Ohms. These improvements are inversely proportional to the TX output impedance, and it shows the importance of optimally adjusted Tx output impedance to achieve an optimum signal amplitude and slope to achieve optimal PPA.

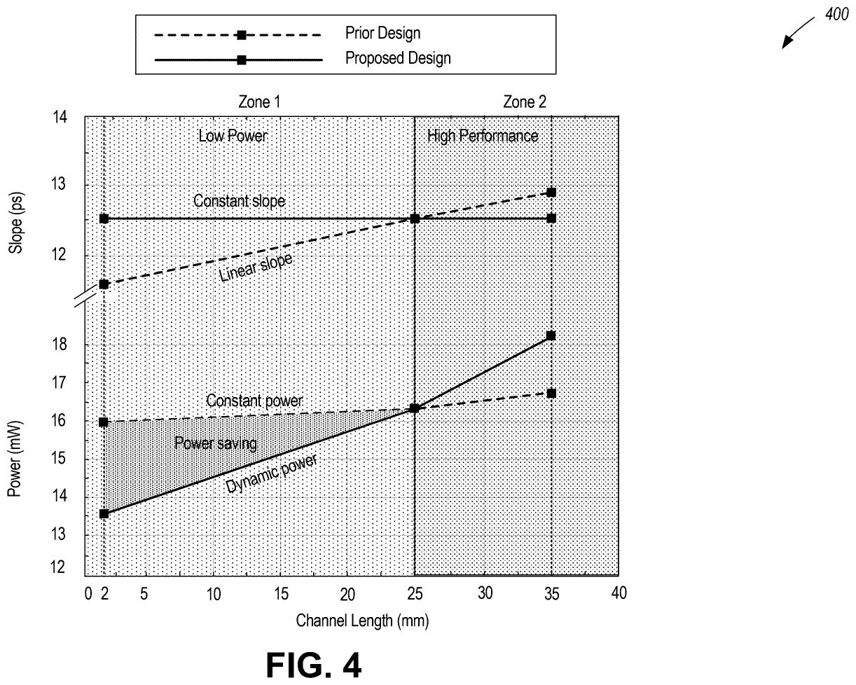

FIG. 4 illustrates graph 400 of power consumption and slope comparison between prior techniques and the disclosed techniques across channel length, in accordance with some embodiments. FIG. 4 simulation results illustrate the capability of the proposed design in optimizing power and performance across various channel lengths, contrary to the constant impedance method in the prior design with power wastage and non-consistent performance (slope) at the low power Zone 1. The shaded area shows the power saving of the proposed design at Zone 1. When the load increases with a longer channel length, the proposed design dynamically increases its power to maintain the performance. In contrast, the prior design performance suffers, which is highlighted in the high-performance Zone 2. FIG. 4 shows that the proposed design is adaptive to avoid overdesign and to achieve the best PPA.

Another benefit of the proposed design is using Vref in lieu of a precision resistor. Generating an accurate reference voltage with a bandgap reference voltage is cheaper for monolithic chip design. This approach eliminates the need for an internal/external precision reference resistor, which reduces board area, cost, and testing time.

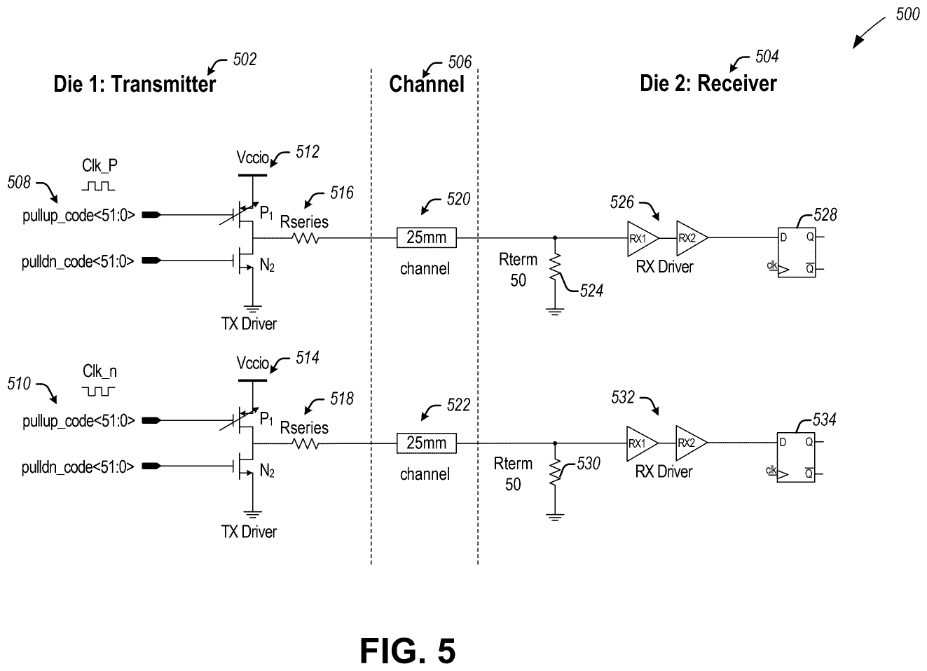

FIG. 5 is a block diagram of a transceiver system 500 without receiver calibration circuits, in accordance with some embodiments. Referring to FIG. 5, TRX system 500 includes a Tx 502, an Rx 504, and one or more communication channels 506, coupling the Tx 502 and the Rx 504.

In some aspects, Tx 502 includes a first Tx driver circuit 512 and a second Tx driver circuit 514. Each of the Tx driver circuits can include a pull-up transistor (e.g., PMOS transistor P1) and a pull-down transistor (e.g., NMOS transistor N2).

The first Tx driver circuit 512 can be configured to generate an output signal (e.g., a positive clock signal) based on activation signals 508. The generated output signal is communicated to Rx 504 via resistor 516, communication channel 520, and termination resistor 524. At Rx 504, the output signal is processed by Rx driver circuit 526 and flip-flop circuit 528.

The second Tx driver circuit 514 can be configured to generate an output signal (e.g., a negative clock signal) based on activation signals 510. The generated output signal is communicated to Rx 504 via resistor 518, communication channel 522, and termination resistor 530. At Rx 504, the output signal is processed by Rx driver circuit 532 and flip-flop circuit 534.

The simulation results shown in FIG. 4 achieved their performance by employing two calibrations in sequence, as depicted in FIGS. 2 and 6A-7B.

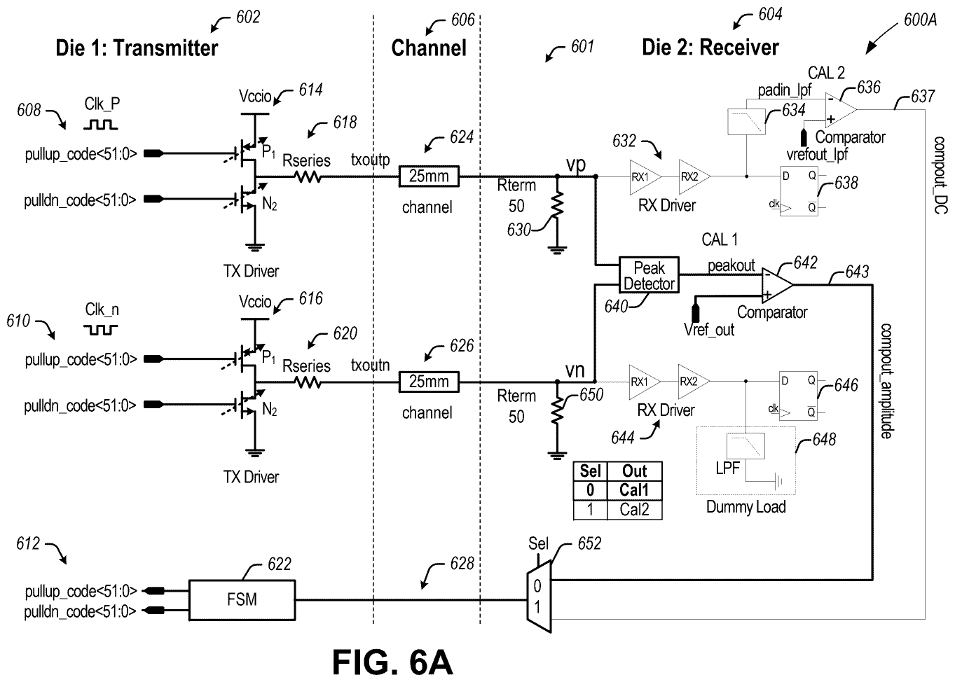

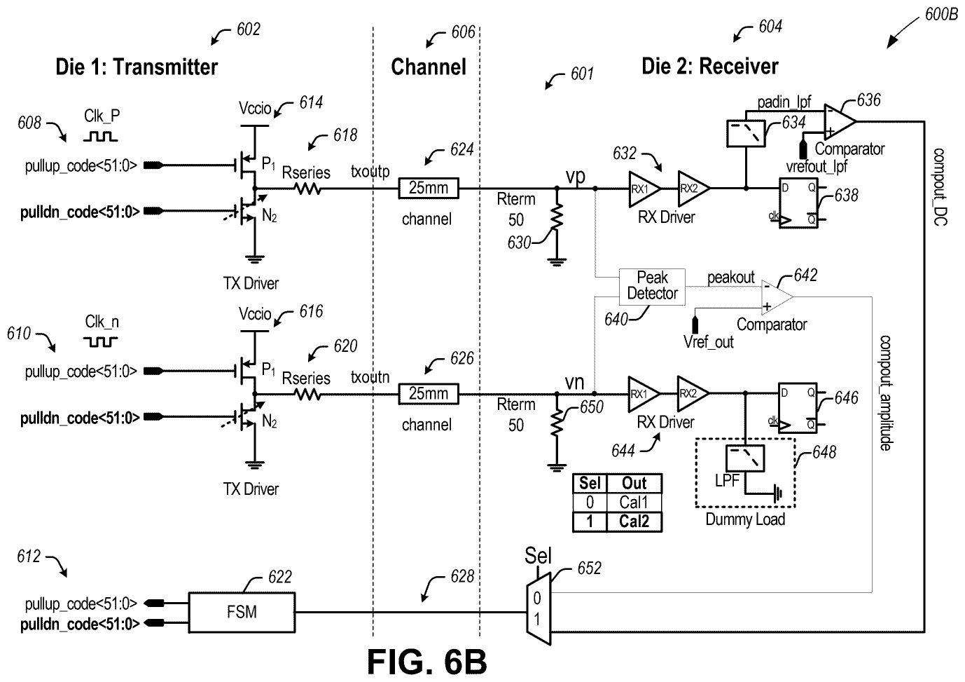

FIG. 5 presents a TRX chain, which employs constant Tx and Rx impedance. In contrast, FIG. 2, as well as FIGS. 6A-6B, show the proposed TRX chain design, which includes two calibration loops: the first is for amplitude and slope calibration (Cal 1), and the second is for DC calibration (Cal 2).

FIG. 6A illustrates diagram 600A of a transceiver system 601 with a highlighted communication path used during amplitude and slope calibration, in accordance with some embodiments. TRX system 601 can be the same as TRX system 200 of FIG. 2.

Referring to FIG. 6A, the TRX system 601 includes a transmitter 602 (also referred to as Tx 602), a receiver 604 (also referred to as Rx 604), and one or more communication channels 606 coupling the Tx 602 and the Rx 604.

In some aspects, Tx 602 includes a first Tx driver circuit 614 and a second Tx driver circuit 616. Each of the Tx driver circuits can include a pull-up transistor (e.g., PMOS transistor P1) and a pull-down transistor (e.g., NMOS transistor N2).

The first Tx driver circuit 614 communicates a first output signal to Rx 604 via resistor 618, communication channel 624, and termination resistor 630.

The second Tx driver circuit 616 communicates a second output signal to Rx 604 via resistor 620, communication channel 626, and termination resistor 650.

The first Tx driver circuit 614 can be configured based on activation signals 608, and the second Tx driver circuit 616 can be configured based on activation signals 610. In some aspects, activation signals 608 and 610 can include one or more pull-up codes and one or more pull-down codes, which can be used to activate (or deactivate) corresponding pull-up links (e.g., pull-up transistors) and pull-down links (e.g., pull-down transistors) of the first Tx driver circuit 614 and the second Tx driver circuit 616.

In some aspects, Tx 602 includes a finite state machine (FSM) circuit 622 configured to generate activation signals 612 based on receiver calibration signals received from the multiplexer circuit 652 via communication channel 628. In some aspects, activation signals 608 and 610 are the same as activation signals 612.

The Rx 604 includes a first calibration circuit (also referred to as Cal 1), a second calibration circuit (also referred to as Cal 2), Rx driver circuits 632 and 644, a flip-flop circuit 646, a dummy load 648, and a multiplexer circuit 652.

The first calibration circuit can include a peak detector circuit 640 and a comparator circuit 642. The second calibration circuit can include a DCD detector circuit 634, a flip-flop circuit 638, and a comparator circuit 636. In some aspects, the DCD detector circuit 634 can be a low-pass filter (LPF) (also referred to as LPF 634).

In operation, the Rx driver circuit 632 generates a first received signal based on the first output signal. The Rx driver circuit 644 generates a second received signal based on the second output signal.

The peak detector circuit 640 of the first calibration circuit generates a peak output signal (e.g., peakout) based on the amplitude of the first output signal and the amplitude of the second output signal. The comparator circuit 642 generates a first calibration signal 643 based on the peak output signal and a reference voltage signal (e.g., Vref_out), which can be based on a desired amplitude/slope for the signals received by the Rx 604 via the one or more communication channels 606.

The DCD detector circuit 634 generates a DCD signal (padin_lpf) based on the first received signal. The DCD signal is indicative of the DCD associated with the first received signal. The comparator circuit 636 generates a second calibration signal 637 based on the DCD signal and a reference voltage signal (e.g., Vrefout_lpf). In some aspects, Vrefout_lpf is one-half of the supply voltage of the Rx 604.

The first calibration signal 643 and the second calibration signal 637 are communicated to multiplexer circuit 652. The multiplexer circuit 652 outputs the first calibration signal 643 and the second calibration signal 637 as Rx calibration signals.

In some aspects, FSM circuit 622 generates one or more pull-up codes and one or more pull-down codes as the activation signals 612 (which are the same as activation signals 252 and 254) based on the first calibration signal 643. The number of pull-up links of the first Tx driver circuit 614 (and/or the second Tx driver circuit 616) is adjusted based on the one or more pull-up codes. In some aspects, the number of pull-down links of the first Tx driver circuit 614 (and/or the second Tx driver circuit 616) is adjusted based on the one or more pull-down codes.

In some aspects, FSM circuit 622 generates one or more additional pull-down codes (which can be part of activation signals 612) based on the second calibration signal 637. The number of pull-down links of the first Tx driver circuit 614 (and/or the second Tx driver circuit 616) is adjusted further based on the one or more additional pull-down codes.

FIG. 6B illustrates diagram 600B of the transceiver system 601 with a highlighted communication path used during duty cycle (DC)-based calibration, in accordance with some embodiments.

FIG. 6A highlights the Cal 1 calibrator in bold, which is a calibration mechanism to regulate the amplitude and slope. The peak detector circuit 640 is positioned close to the Rx input to measure the amplitude and slope of the differential clock signal transmitted by the Tx 602. The peak detector output is then read by a low offset comparator (e.g., comparator circuit 642). A Vref is determined by the user and chosen based on the eye margin requirements for the specific IO standard at the RX input. The comparator's output is feedback cross-die to the Tx 602, where it is captured by the FSM circuit 622. The FSM circuit 622 processes the incoming signal and issues commands to the Tx driver circuits to adjust the output impedance based on the comparator output until the peak detector output is equal to the Vref. Both pull-up transistor (PMOS) and pull-down transistor (NMOS) elements of the TX driver circuits are fed with the same calibration code.

FIG. 6B illustrates that Cal 2 calibration can begin after the completion of Cal 1 calibration. The DC of the Rx signal is detected prior to the sampling flip-flop circuit 638 using a DCD detector (e.g., LPF 634), which averages the signal to obtain the DC information. The output from the LPF is then compared with the Vref (e.g., by comparator circuit 636), which is set at half of the supply voltage (e.g., with a division-by-2 voltage divider). The comparator decision is feedback cross-die to the Tx 602, where it is captured by the FSM circuit 622. The FSM circuit 622 processes the incoming signal and issues commands to the pull-down (NMOS) element only of the TX driver circuits until the DCD approximates zero.

A multiplexer circuit 652 is used to select Cal 1 calibration and Cal 2 calibration sequentially by the FSM circuit 622.

The above processes can be used to ensure the Tx driver's impedance is accurately calibrated, which is essential to preserve the integrity of the signal across the channel for high-speed data communication.

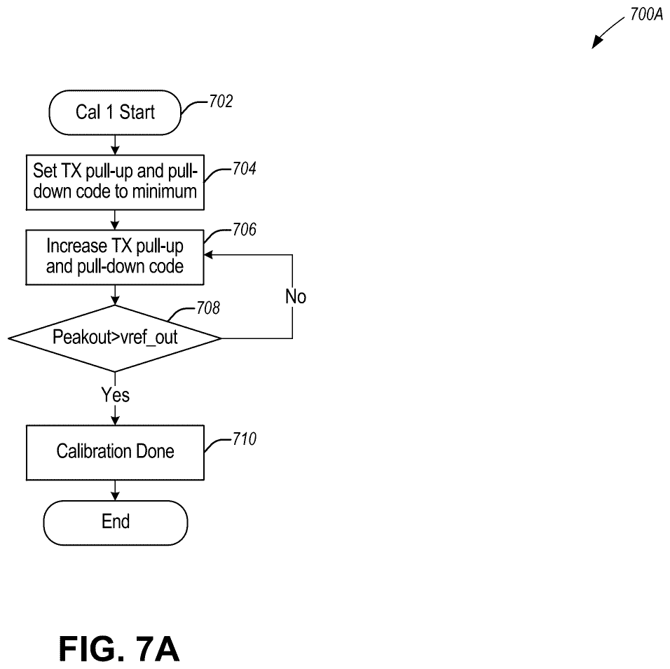

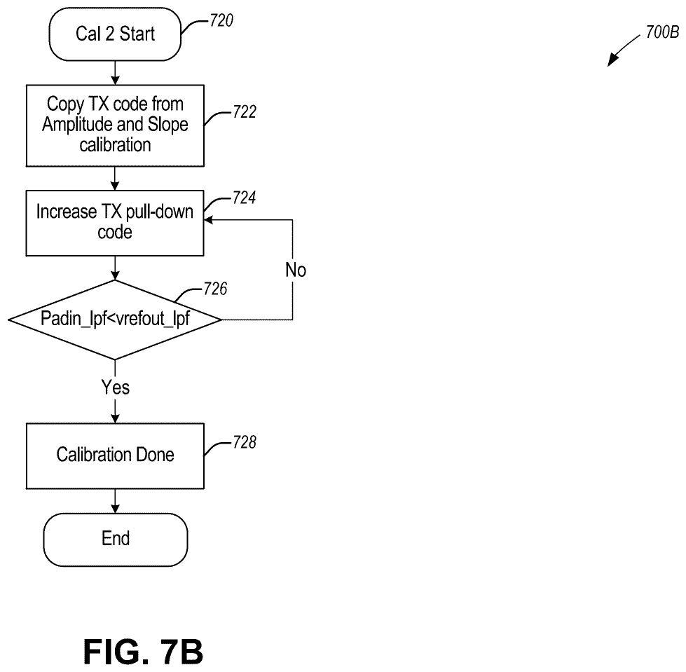

FIG. 7A is a flow diagram of an example method 700A for performing amplitude and slope calibration, in accordance with some embodiments. Referring to FIG. 7A, method 700A can be performed in connection with Cal 1 calibration by the first calibration circuit.

At operation 702, Cal 1 calibration starts.

At operation 704, the Tx driver circuit pull-up and pull-down codes can be set to a minimum.

At operation 706, the Tx driver circuit pull-up and pull-down codes can be increased.

At operation 708, a determination is made on whether the peakout signal is greater than Vref_out. If it is not greater, processing continues at operation 706. If it is greater, processing continues at operation 710 when calibration is concluded.

FIG. 7B is a flow diagram of an example method 700B for performing DC-based calibration, in accordance with some embodiments. Referring to FIG. 7B, method 700B can be performed in connection with Cal 2 calibration by the second calibration circuit.

At operation 720, Cal 2 calibration starts.

At operation 722, the Tx code (e.g., pull-up and pull-down code that are part of the activation signals configured during Cal 1 calibration) is obtained.

At operation 724, the Tx pull-down code is increased.

At operation 726, a determination is made on whether signal padin_lpf is smaller than Vrefout_lpf. If it is not smaller, processing continues at operation 724. If it is smaller, processing continues at operation 728 when calibration is concluded.

FIG. 7A shows the calibration flow for amplitude and slope, referred to as Cal 1. The calibration begins by setting the Tx output impedance to its lowest code, which corresponds to the highest output impedance for both the pull-up and pull-down transistor sections. At this stage, the output from the amplitude and slope detector is expected to be below the Vref. The FSM circuit will command the Tx to incrementally increase the pull-up and pull-down codes to reduce its output impedance and, as a result, raise the amplitude, slope, and overshoot until it achieves the targeted value set by the Vref. The FSM circuit will issue calibration done (at operation 710) to signal the completion of Cal 1 calibration.

By design, the pull-down strength can be set to be weaker than the pull-up strength when both are assigned the same Tx code after amplitude and slope calibration. The goal of DC calibration can be to enhance the pull-down strength to equalize the slope of the rise and fall times, thereby reducing DCD at the Rx 204. This reduction in DCD is essential for increasing the timing margin available at the RX's timing flop to sample the incoming signal. FIG. 7B shows the Cal 2 calibration flow, which begins by copying the codes from the Cal 1 calibration and then increasing the code of the pull-down element until it matches the pull-up element strength. The FSM circuit will issue calibration done (at operation 728) to signal the completion of Cal 2 calibration.

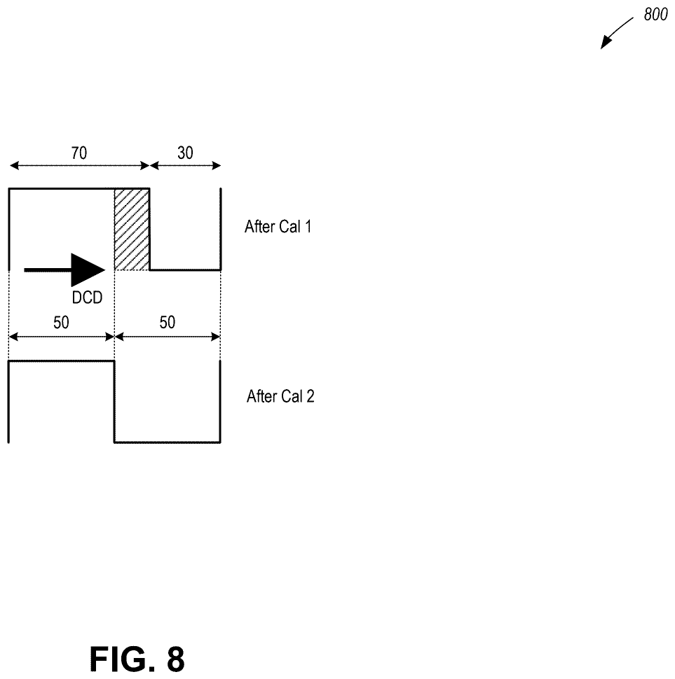

FIG. 8 illustrates diagram 800 of the duty cycle adjustment of a waveform in accordance with some embodiments. FIG. 8 shows the DCD residual after Cal 1 and how Cal 2 is adjusting the edge of the waveform to achieve 50% DC.

In some aspects, an unterminated configuration is used for shorter channel length and lower data rate, distinguished by the full swing amplitude saturated when it reaches the supply voltage.

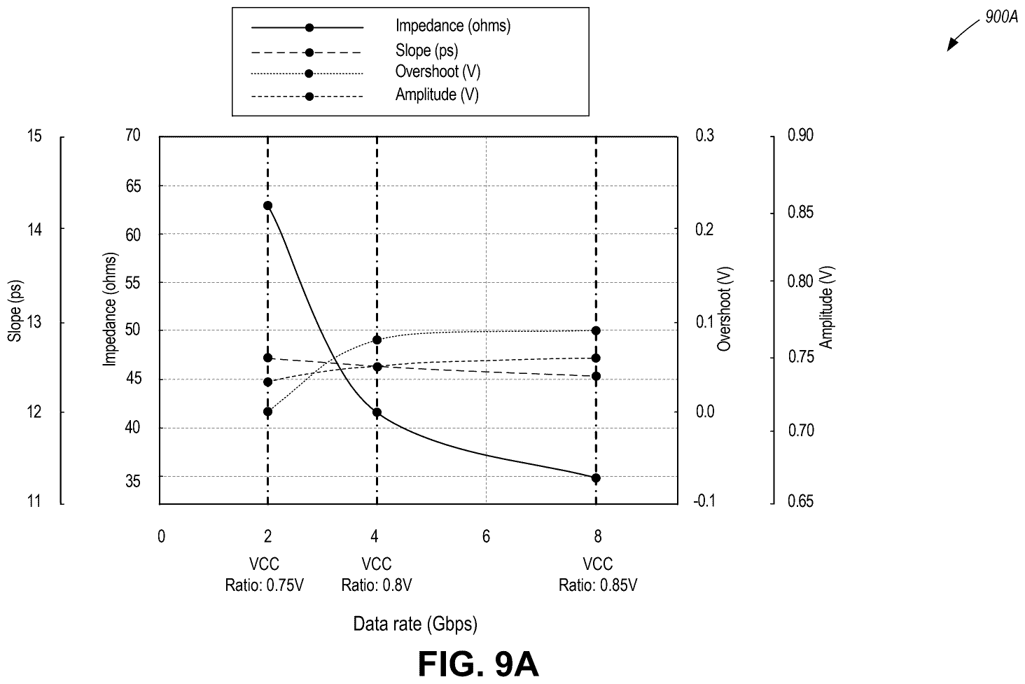

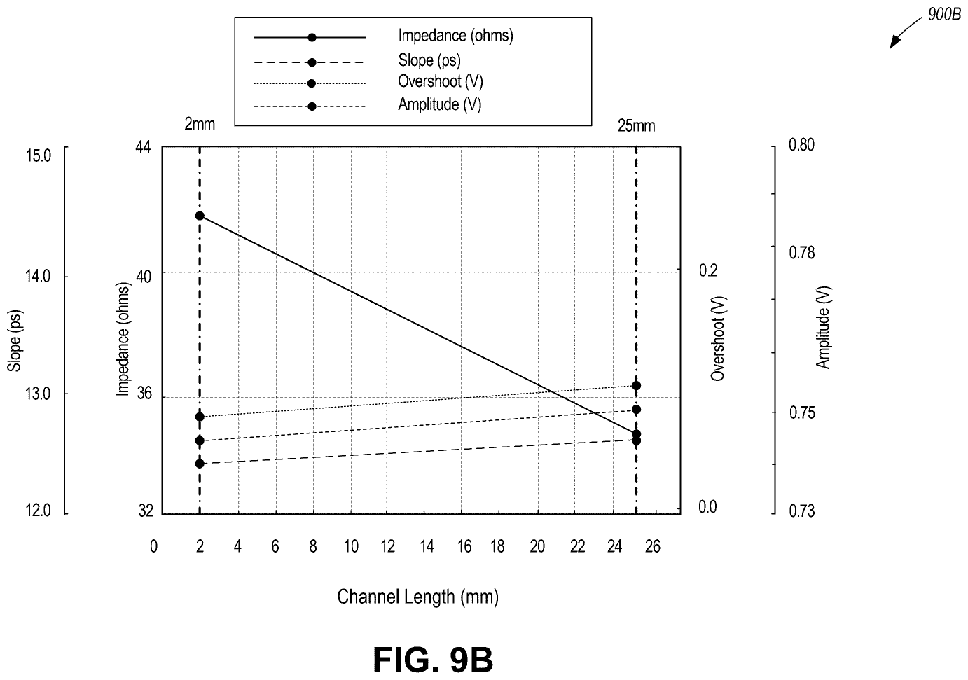

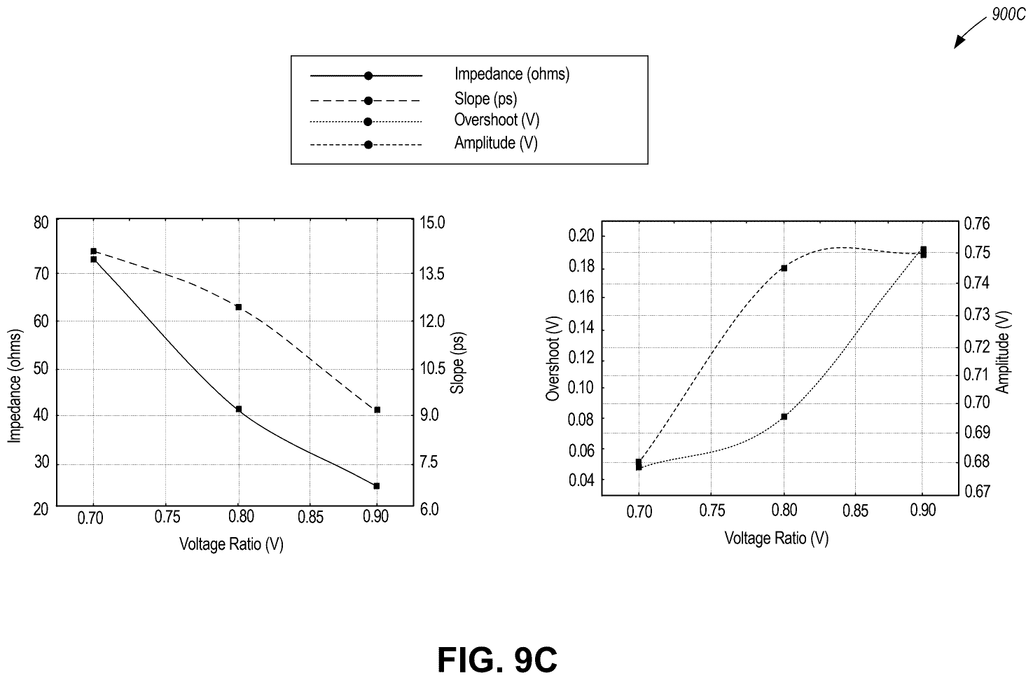

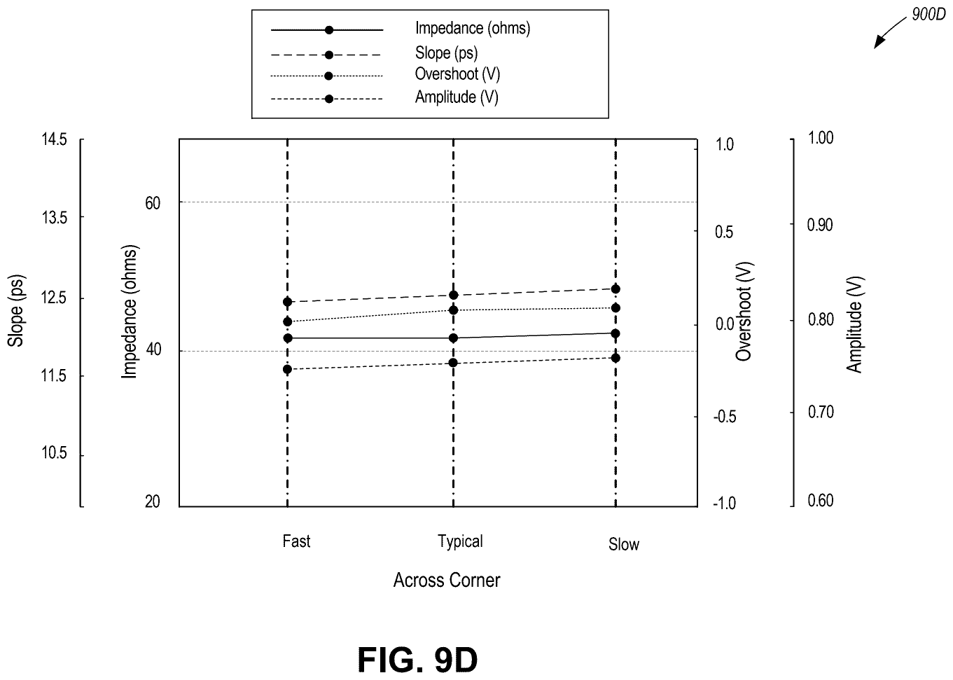

FIG. 9A is a graph 900A of performance across data rates, in accordance with some embodiments. FIG. 9A shows the selection of optimal Vref labeled as “VCC ratio” for each data rate to maintain a consistent slope, peak-to-peak amplitude, and overshoot. The impedance is reduced when the data rate is increasing to maintain consistent performance. The Vref is a user-selectable parameter to achieve the desired performance metrics.

FIG. 9B is a graph 900B of performance across channel length at 8 Gbps, in accordance with some embodiments. FIG. 9B shows how Tx impedance is adjusted dynamically to adapt to channel length variation and achieve constant amplitude, slope, and overshoot.

FIG. 9C illustrates graphs 900C of performance with Vref settings at 8 Gbps, in accordance with some embodiments. FIG. 9C shows how the Vref can be set by the users for slope, amplitude, and overshoot adjustment, providing greater flexibility to the user to tweak the desired performance metrics.

FIG. 9D is a graph 900D of performance across process corners at 8 Gbps, in accordance with some embodiments. FIG. 9D shows that the proposed calibration can maintain constant performance metrics across process corners.

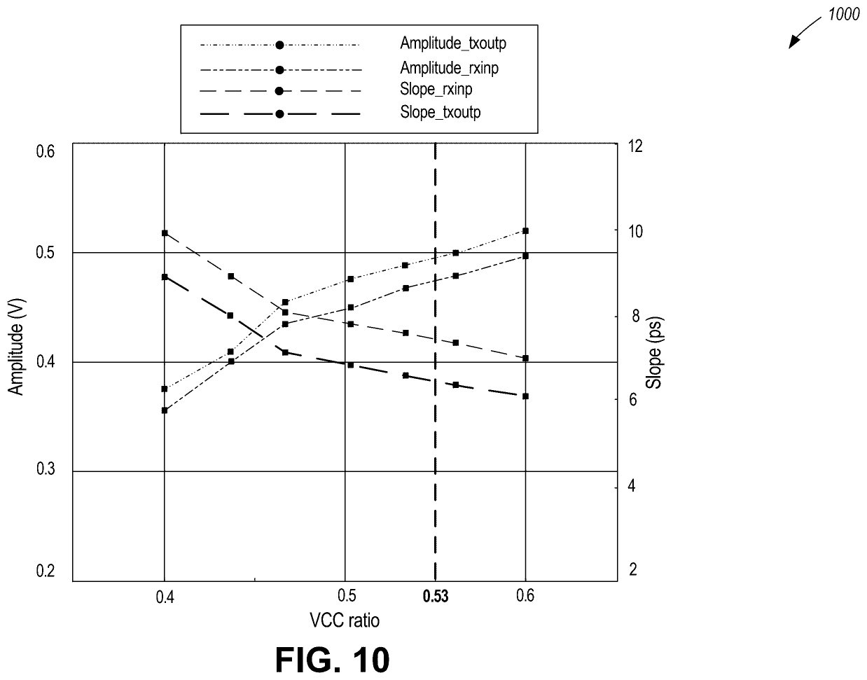

FIG. 10 is a graph 1000 of amplitude and slope proportional to VCC ratio with 50 Ohms termination, in accordance with some embodiments. Simulation results in FIG. 10 show that the 50 Ohms termination based on the voltage divider and parallel resistor principle is employed for high data-rate signals and long channel lengths to reduce RC constants and minimize signal reflection, hence improving SI. The VCC ratio varies between 0.4 and 0.6, and the simulation shows the amplitude is increasing proportional to the VCC ratio due to the reduction of TX output impedance, which contrasts with the unterminated case where the amplitude is saturated to supply voltage at a high VCC ratio. A VCC ratio of 0.53 is chosen for the subsequent simulation results to achieve the desired performance metrics. For a 16 Gbps data rate, the amplitude is 474 mV, which complies with the UCle Standard specification requiring RX eye height greater than 400 mV.

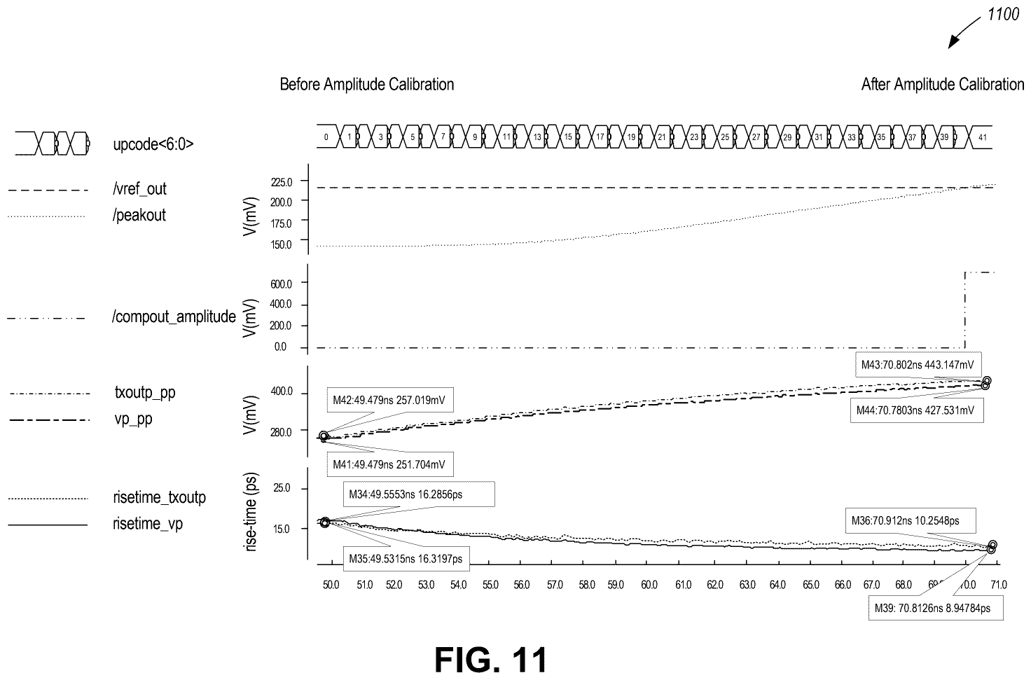

FIG. 11 is a graph 1100 of simulation results of amplitude and slope calibration, in accordance with some embodiments. FIG. 11 shows the simulation results of the Cal 1 closed-loop calibration. The calibration begins with the Tx code set to minimum for the highest output impedance. Calibration continues until the compout_amplitude signal is asserted (e.g., as illustrated in FIG. 6A), indicating calibration is done where the pull-up and pull-down codes have reached the optimum impedance code. During the training sequence, the following can be observed: the Tx driver positive output clock net, txoutp and RX positive input clock net, and vp amplitude increases when the calibration code increases. Initially, the txoutp amplitude was measured at 257 mV and increased to 443 mV after calibration. The slope improved from 16.29 ps to 10.25 ps. For the vp, the amplitude before calibration was 251 mV and improved to 427.53 mV post-calibration. The vp net slope shows improvement from 16.32 ps to 8.95 ps. This shows that the proposed calibrator found the optimum Tx output impedance to improve SI and maximize eye opening with a VCC ratio target set to 0.53.

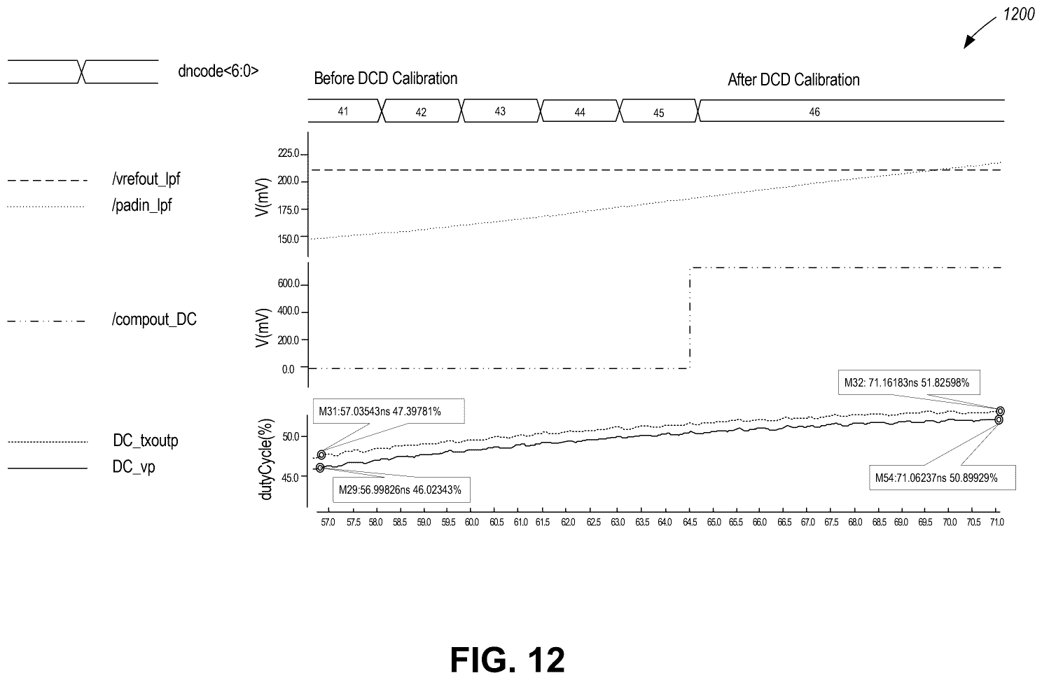

FIG. 12 is a graph 1200 of simulation results of DC-based calibration, in accordance with some embodiments. FIG. 12 shows the simulation results of the DC calibrator during the Cal 2 calibration. FIG. 12 shows the DC before and after calibration. Before the commencement of Cal 2 calibration, the simulation waveform shows that the Tx pull-down code, dncode<6: 0> (e.g., FIG. 6B), starts at code 41, which was inherited from Cal 1 calibration. The calibration continues until the compout_DC signal is asserted, indicating the end of Cal 2 calibration and dncode<6: 0>stops at code 46. The DC of net vp improved from 46.02% to 50.89%. This shows that Cal 2 calibration has been successful in reducing DCD <1% to increase timing margin and thus easing timing closure at the Rx timing flop input.

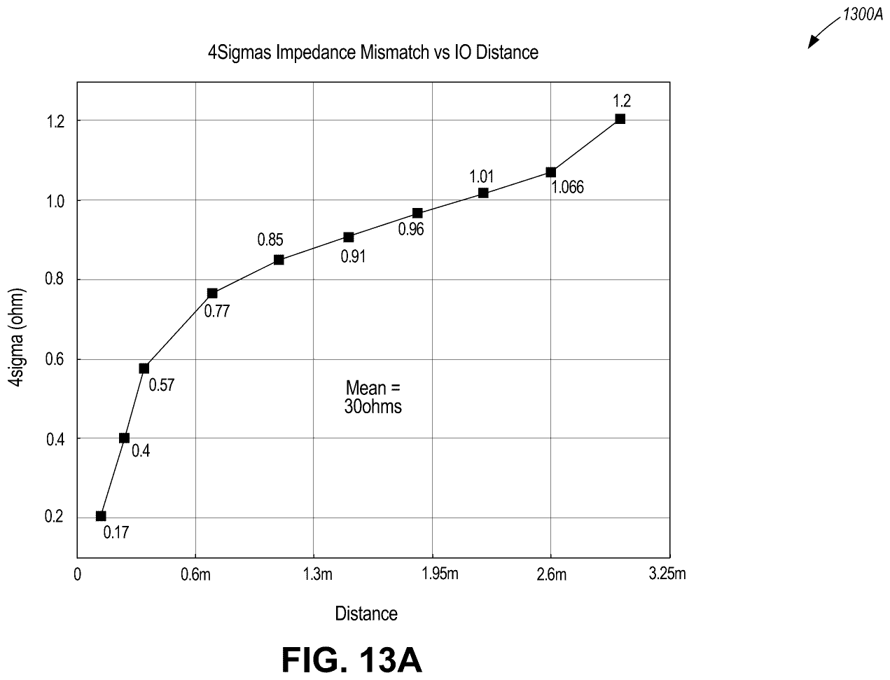

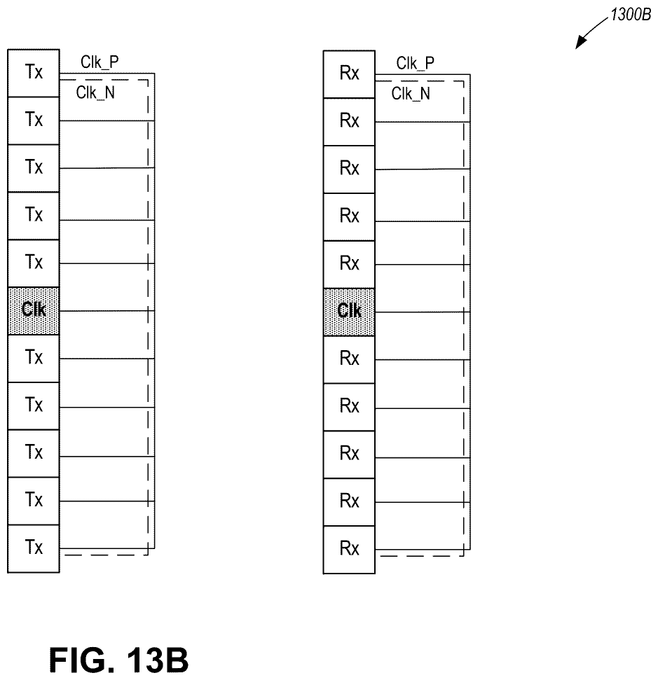

FIG. 13A is a graph 1300A of simulation results for spatial transmit impedance mismatch with input/output (IO) distance, in accordance with some embodiments.

FIG. 13B is a block diagram 1300B of a floorplan for matching between clock IO and data IOs, in accordance with some embodiments.

In some aspects, the proposed calibration techniques can be used to calibrate the differential clock IOs. Then, the calibration code can be copied to all data IOs in the channel shoreline. The spatial mismatch between the calibrated clock IO Tx output impedance and other data IOs located at some distance away from the clock IOs is shown in FIG. 13A. As the data IO distance from the clock IO increases, so does the impedance mismatch. This mismatch increases at a higher rate up to approximately 0.6 mm with a 4-sigma mismatch of 0.77 Ohms (2.6%) and then levels off beyond that. With an IO distance of 3 mm, the impedance mismatch reaches 1.2 Ohms, which is a 4% deviation from the 30 Ohms reference. The increasing impedance mismatch with distance can lead to degradation in SI, affecting amplitude and slope. The mismatch can be compensated by overdesign but reduces the PPA. To mitigate this, it is recommended to position the calibrated clock IO at the center of the data IOs to reduce the spatial mismatch, as illustrated in FIG. 13B.

Calibrating a single clock IO reduces calibration time and die area by minimizing the need for multiple calibrators. However, for longer shoreline floorplans, adding more calibrators can break the maximum spatial mismatch distance, thus improving matching for far-end data IOs. In some aspects, channel routes can be matched to maintain good matching between all IOs to improve skew and timing margin.

In some aspects, the disclosed techniques can be used to configure a calibrator to dynamically adjust the Tx output impedance to achieve an optimum impedance and, thus, a fixed RC constant. Simulation shows that the proposed calibrator can regulate the received signal amplitude, slope, overshoot, and DC for varying TRX conditions, e.g., channel length, device corners, and data rate, to maximize the eye opening, good SI, and to prevent EOS condition.

In some aspects, a user-selectable reference voltage is used to control the desired signal regulation level, thus avoiding an expensive precision reference resistor or tester time as required in the prior method with constant impedance. In some aspects, the disclosed techniques result in improved PPA because overdesign of the prior methods is avoided. In some aspects, the proposed calibration techniques can be effective for short channel length wireline TRX, such as UCle and AIB die-to-die IO standards, because short channel length does not require strict impedance matching terminations.

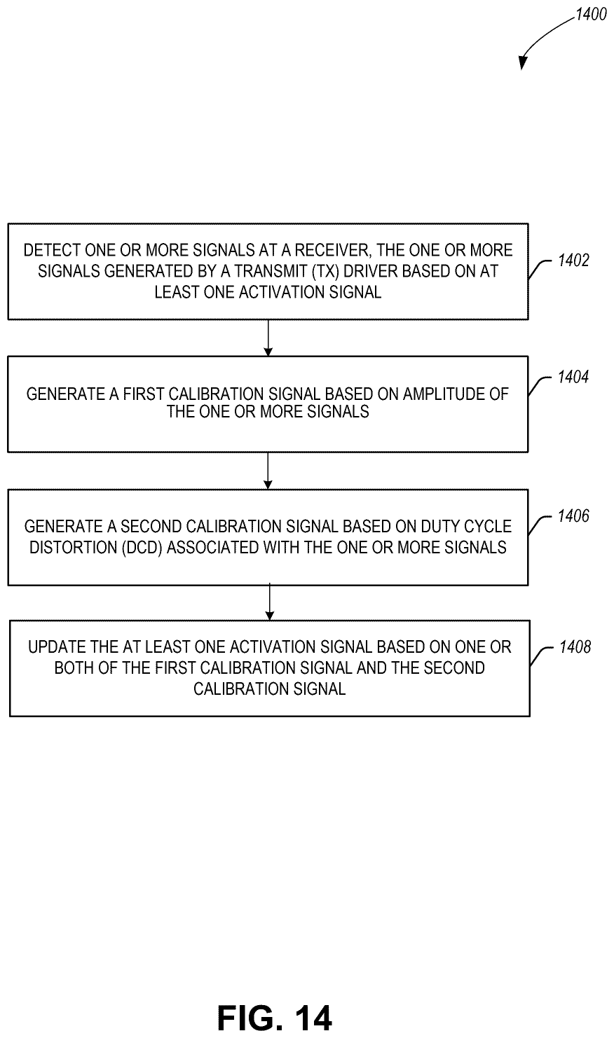

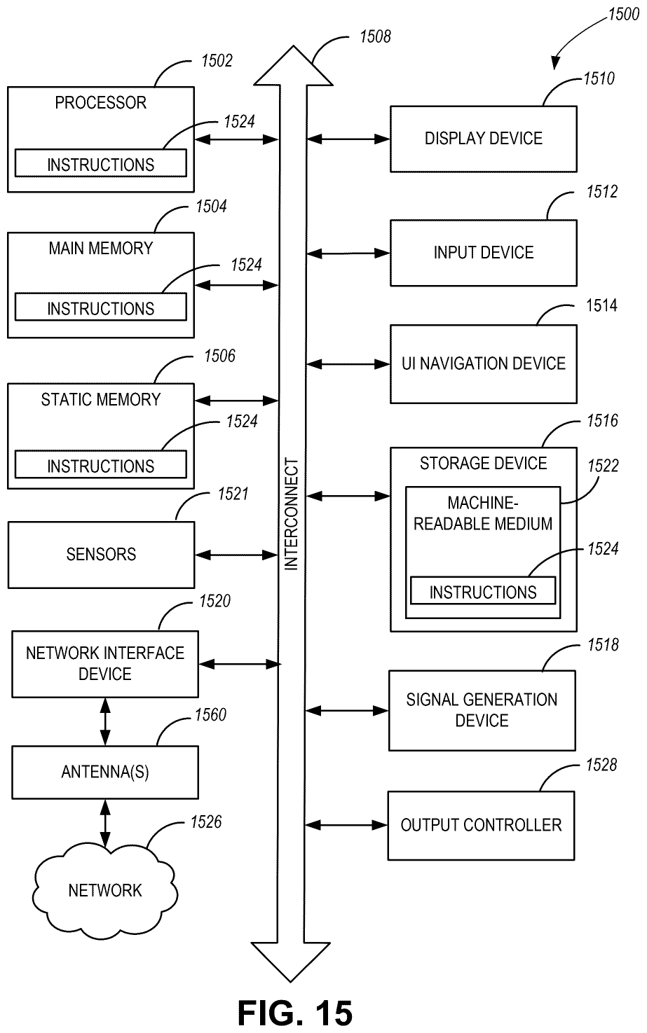

FIG. 14 is a flow diagram of an example method 1400 for performing receiver calibration, in accordance with some embodiments. Referring to FIG. 14, method 1400 includes operations 1402, 1404, 1406, and 1408, which may be executed by a processor, an embedded controller, a receiver circuit, a transceiver circuit, or another processor of a computing device (e.g., hardware processor 1502 of machine 1500 illustrated in FIG. 15, which can include one or more of the circuits discussed in connection with FIGS. 1-13B). In some embodiments, one or more of the circuits discussed in connection with FIGS. 1-13B can perform the functionalities listed in FIG. 14, as well as one or more of the examples listed below.

At operation 1402, one or more signals are detected at a receiver (e.g., first output signal 213 and second output signal 239). The one or more signals are generated by a transmit (Tx) driver based on at least one activation signal (e.g., activation signals 256).

At operation 1404, a first calibration signal (e.g., first calibration signal 231) is generated based on the amplitude of one or more signals.

At operation 1406, a second calibration signal (e.g., second calibration signal 225) is generated based on duty cycle distortion (DCD) associated with the one or more signals.

At operation 1408, the at least one activation signal (e.g., activation signals 256) is updated based on one or both of the first calibration signal and the second calibration signal.

FIG. 15 illustrates a block diagram of an example machine 1500 upon which any one or more of the techniques (e.g., methodologies) discussed herein may perform. In alternative embodiments, the machine 1500 may operate as a standalone device or may be connected (e.g., networked) to other machines. In a networked deployment, machine 1500 may operate in the capacity of a server machine, a client machine, or both in server-client network environments. In an example, machine 1500 may function as a peer machine in a peer-to-peer (P2P) (or other distributed) network environment. The machine 1500 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1500 may include a hardware processor 1502 (e.g., a central processing unit (CPU), a graphics processing unit (GPU), a hardware processor core, or any combination thereof), a main memory 1504, and a static memory 1506, some or all of which may communicate with each other via an interlink (e.g., bus) 1508. In some aspects, the main memory 1504, the static memory 1506, or any other type of memory (including cache memory) used by machine 1500 can be configured based on the disclosed techniques or can implement the disclosed memory devices.

Specific examples of main memory 1504 include Random Access Memory (RAM) and semiconductor memory devices, which may include, in some embodiments, storage locations in semiconductors such as registers. Specific examples of static memory 1506 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1500 may further include a display device 1510, an input device 1512 (e.g., a keyboard), and a user interface (UI) navigation device 1514 (e.g., a mouse). In an example, the display device 1510, the input device 1512, and the UI navigation device 1514 may be a touchscreen display. The machine 1500 may additionally include a storage device (e.g., drive unit or another mass storage device) 1516, a signal generation device 1518 (e.g., a speaker), a network interface device 1520, and one or more sensors 1521, such as a global positioning system (GPS) sensor, compass, accelerometer, or other sensors. The machine 1500 may include an output controller 1528, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1502 and/or instructions 1524 may comprise processing circuitry and/or transceiver circuitry.

The storage device 1516 may include a machine-readable medium 1522 on which one or more sets of data structures or instructions 1524 (e.g., software) embodying or utilized by any one or more of the techniques or functions described herein can be stored. Instructions 1524 may also reside, completely or at least partially, within the main memory 1504, within static memory 1506, or the hardware processor 1502 during execution thereof by the machine 1500. In an example, one or any combination of the hardware processor 1502, the main memory 1504, the static memory 1506, or the storage device 1516 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1522 is illustrated as a single medium, the term “machine-readable medium” may include a single medium or multiple media (e.g., a centralized or distributed database and/or associated caches and servers) configured to store instructions 1524.

An apparatus of machine 1500 may be one or more of a hardware processor 1502 (e.g., a central processing unit (CPU), a graphics processing unit (GPU), a hardware processor core, or any combination thereof), a main memory 1504 and a static memory 1506, one or more sensors 1521, a network interface device 1520, one or more antennas 1560, a display device 1510, an input device 1512, a UI navigation device 1514, a storage device 1516, instructions 1524, a signal generation device 1518, and an output controller 1528. The apparatus may be configured to perform one or more of the methods and/or operations disclosed herein. The apparatus may be intended as a component of machine 1500 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1500 and that causes machine 1500 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1524 may further be transmitted or received over a communications network 1526 using a transmission medium via the network interface device 1520 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 1520 may include one or more physical jacks (e.g., Ethernet, coaxial, or phone jacks) or one or more antennas to connect to the communications network 1526. In an example, the network interface device 1520 may include one or more antennas 1560 to wirelessly communicate using at least one single-input multiple-output (SIMO), multiple-input multiple-output (MIMO), or multiple-input single-output (MISO) techniques. In some examples, the network interface device 1520 may wirelessly communicate using multiple-user MIMO techniques. The term “transmission medium” shall be taken to include any intangible medium that can store, encode, or carry instructions for execution by the machine 1500 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is a transceiver circuit, comprising a first transmit (Tx) driver circuit coupled to a first terminal of a first communication channel; a first receive (Rx) driver circuit including an input terminal coupled to a second terminal of the first communication channel; a peak detector circuit including a first input terminal coupled to the second terminal of the first communication channel; a first comparator circuit including a first input terminal coupled to an output terminal of the peak detector circuit and a second input terminal to receive a first reference voltage signal; and a multiplexer circuit including a first input terminal coupled to an output of the first comparator circuit.

In Example 2, the subject matter of Example 1 includes a duty cycle distortion (DCD) detector circuit, including an input terminal coupled to an output terminal of the first Rx driver circuit.

In Example 3, the subject matter of Example 2 includes a second comparator circuit, including a first input terminal coupled to an output terminal of the DCD detector circuit and a second input terminal to receive a second reference voltage signal.

In Example 4, the subject matter of Example 3 includes subject matter where an output of the second comparator circuit is coupled to a second input terminal of the multiplexer circuit.

In Example 5, the subject matter of Examples 2-4 includes subject matter where the DCD detector circuit comprises a low-pass filter (LPF) circuit.

In Example 6, the subject matter of Examples 2-5 includes a flip-flop circuit including an input terminal coupled to the output terminal of the first Rx driver circuit.

In Example 7, the subject matter of Examples 1-6 includes a second Tx driver circuit coupled to a first terminal of a second communication channel and a second Rx driver circuit including an input terminal coupled to a second terminal of the second communication channel.

In Example 8, the subject matter of Example 7 includes the subject matter where the input terminal of the second Rx driver circuit is coupled to a second input terminal of the peak detector circuit.

In Example 9, the subject matter of Example 8 includes subject matter where an output terminal of the second Rx driver circuit is coupled to a low-pass filter (LPF) circuit and a flip-flop circuit.

In Example 10, the subject matter of Examples 1-9 includes a finite state machine (FSM) circuit including an input terminal coupled to an output terminal of the multiplexer circuit.

In Example 11, the subject matter of Example 10 includes subject matter where an output terminal of the FSM circuit is coupled to an input terminal of the first Tx driver circuit.

In Example 12, the subject matter of Examples 4-11 includes subject matter where the transceiver circuit comprises a system-on-chip (SoC), the SoC including an integrated circuit (IC), the IC including two or more of the first Rx driver circuit, the peak detector circuit, the first comparator circuit, the multiplexer circuit, the DCD detector circuit, and the second comparator circuit.

Example 13 is a transceiver apparatus comprising: a transmitter circuit, the transmitter circuit comprising: a first transmit (Tx) driver circuit to generate a first output signal based on one or more activation signals; and a finite state machine (FSM) circuit coupled to the first Tx driver circuit, the FSM circuit to generate the one or more activation signals based on receiver calibration signals; and a receiver circuit, the receiver circuit coupled to the transmitter circuit via one or more communication channels, and the receiver circuit comprising: a first receive (Rx) driver circuit to generate a first received signal based on the first output signal; a first calibration circuit to receive the first output signal via the one or more communication channels and generate a first calibration signal based on an amplitude of the first output signal; a second calibration circuit coupled to the first Rx driver circuit, the second calibration circuit to generate a second calibration signal based on duty cycle distortion (DCD) associated with the first received signal; and a multiplexer circuit coupled to the first calibration circuit and the second calibration circuit, the multiplexer circuit to generate the receiver calibration signals based on at least one of the first calibration signal and the second calibration signal.

In Example 14, the subject matter of Example 13 includes subject matter where the transmitter circuit comprises a second Tx driver circuit to generate a second output signal based on the one or more activation signals.

In Example 15, the subject matter of Example 14 includes subject matter where the receiver circuit comprises a second Rx driver circuit to generate a second receive signal based on the second output signal and a low-pass filter (LPF) to filter the second output signal and generate a filtered output signal.

In Example 16, the subject matter of Examples 14-15 includes subject matter where the first calibration circuit comprises a peak detector circuit to generate a peak output signal based on an amplitude of the first output signal and the second output signal.

In Example 17, the subject matter of Example 16 includes subject matter where the first calibration circuit comprises a comparator circuit to generate the first calibration signal based on the peak output signal and a reference voltage signal.

In Example 18, the subject matter of Examples 13-17 includes subject matter where the second calibration circuit comprises a duty cycle distortion (DCD) detector circuit to generate a DCD signal based on the first received signal, and the DCD signal indicative of the DCD associated with the first received signal.

In Example 19, the subject matter of Example 18 includes subject matter where the second calibration circuit comprises a comparator circuit coupled to the DCD detector circuit, the comparator circuit to generate the second calibration signal based on the DCD signal and a reference voltage signal.

In Example 20, the subject matter of Example 19 includes subject matter where the reference voltage signal is one-half of a supply voltage of the receiver circuit.

In Example 21, the subject matter of Examples 19-20 includes subject matter where the DCD detector circuit comprises a low-pass filter (LPF) circuit.

In Example 22, the subject matter of Examples 13-21 includes subject matter where the FSM circuit is to generate one or more pull-up codes and one or more pull-down codes as the one or more activation signals based on the first calibration signal; adjust a number of pull-up links of the first Tx driver circuit based on the one or more pull-up codes; and adjust a number of pull-down links of the first Tx driver circuit based on the one or more pull-down codes.

In Example 23, the subject matter of Example 22 includes subject matter where the FSM circuit is to generate one or more additional pull-down codes based on the second calibration signal and adjust the number of pull-down links of the first Tx driver circuit further based on the one or more additional pull-down codes.

In Example 24, the subject matter of Examples 13-23 includes a system on chip (SoC), the SoC including an integrated circuit (IC), the IC including one or both of the receiver circuit and the transmitter circuit.

In Example 25, the subject matter of Examples 13-24 includes a system on chip (SoC), the SoC including an integrated circuit (IC), the IC including two or more of the first Rx driver circuit, the second Rx driver circuit, the first calibration circuit, the second calibration circuit, and the multiplexer circuit.

Example 26 is a method for receiver calibration, the method comprising detecting one or more signals at a receiver, the one or more signals generated by a transmit (Tx) driver based on at least one activation signal, generating a first calibration signal based on an amplitude of the one or more signals; generating a second calibration signal based on duty cycle distortion (DCD) associated with the one or more signals; and updating the at least one activation signal based on one or both of the first calibration signal and the second calibration signal.

In Example 27, the subject matter of Example 26 includes generating one or more pull-up codes and one or more pull-down codes as the at least one activation signal based on the first calibration signal; adjusting a number of pull-up links of the Tx driver circuit based on the one or more pull-up codes; and adjust a number of pull-down links of the Tx driver circuit based on the one or more pull-down codes.

In Example 28, the subject matter of Examples 26-27 includes generating one or more additional pull-down codes based on the second calibration signal and adjusting the number of pull-down links of the Tx driver circuit further based on the one or more additional pull-down codes.

Example 29 is at least one machine-readable medium including instructions that, when executed by processing circuitry, cause the processing circuitry to perform operations to implement any of Examples 1-28.

Example 30 is an apparatus comprising means to implement any of

### Examples 1-28.

Example 31 is a system to implement any of Examples 1-28.

Example 32 is a method to implement any of Examples 1-28.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. A transceiver circuit, comprising a first transmit (Tx) driver circuit coupled to a first terminal of a first communication channel;
a first receive (Rx) driver circuit including an input terminal coupled to a second terminal of the first communication channel;
a peak detector circuit including a first input terminal coupled to the second terminal of the first communication channel;
a first comparator circuit including a first input terminal coupled to an output terminal of the peak detector circuit and a second input terminal to receive a first reference voltage signal; and
a multiplexer circuit including a first input terminal coupled to an output of the first comparator circuit.

2. The transceiver circuit of claim 1, further comprising:
a duty cycle distortion (DCD) detector circuit including an input terminal coupled to an output terminal of the first Rx driver circuit.

3. The transceiver circuit of claim 2, further comprising:
a second comparator circuit including a first input terminal coupled to an output terminal of the DCD detector circuit and a second input terminal to receive a second reference voltage signal.

4. The transceiver circuit of claim 3, wherein an output of the second comparator circuit is coupled to a second input terminal of the multiplexer circuit.

5. The transceiver circuit of claim 2, wherein the DCD detector circuit comprises a low-pass filter (LPF) circuit.

6. The transceiver circuit of claim 2, further comprising:
a flip-flop circuit including an input terminal coupled to the output terminal of the first Rx driver circuit.

7. The transceiver circuit of claim 1, further comprising:
a second Tx driver circuit coupled to a first terminal of a second communication channel; and
a second Rx driver circuit including an input terminal coupled to a second terminal of the second communication channel.

8. The transceiver circuit of claim 7, wherein the input terminal of the second Rx driver circuit is coupled to a second input terminal of the peak detector circuit.

9. The transceiver circuit of claim 8, wherein an output terminal of the second Rx driver circuit is coupled to a low-pass filter (LPF) circuit and a flip-flop circuit.

10. The transceiver circuit of claim 4, wherein the transceiver circuit comprises a system-on-chip (SoC), the SoC including an integrated circuit (IC), the IC including two or more of the first Rx driver circuit, the peak detector circuit, the first comparator circuit, the multiplexer circuit, the DCD detector circuit, and the second comparator circuit.

11. A transceiver apparatus comprising:
a transmitter circuit, the transmitter circuit comprising:
a first transmit (Tx) driver circuit to generate a first output signal based on one or more activation signals; and
a finite state machine (FSM) circuit coupled to the first Tx driver circuit, the FSM circuit to generate the one or more activation signals based on receiver calibration signals; and
a receiver circuit, the receiver circuit coupled to the transmitter circuit via one or more communication channels, and the receiver circuit comprising:
a first receive (Rx) driver circuit to generate a first received signal based on the first output signal;
a first calibration circuit to receive the first output signal via the one or more communication channels and generate a first calibration signal based on an amplitude of the first output signal;
a second calibration circuit coupled to the first Rx driver circuit, the second calibration circuit to generate a second calibration signal based on duty cycle distortion (DCD) associated with the first received signal; and
a multiplexer circuit coupled to the first calibration circuit and the second calibration circuit, the multiplexer circuit to generate the receiver calibration signals based on at least one of the first calibration signal and the second calibration signal.

12. The transceiver apparatus of claim 11, wherein the transmitter circuit comprises:
a second Tx driver circuit to generate a second output signal based on the one or more activation signals.

13. The transceiver apparatus of claim 12, wherein the first calibration circuit comprises:
a peak detector circuit to generate a peak output signal based on an amplitude of the first output signal and the second output signal.

14. The transceiver apparatus of claim 13, wherein the first calibration circuit comprises:
a comparator circuit to generate the first calibration signal based on the peak output signal and a reference voltage signal.

15. The transceiver apparatus of claim 11, wherein the second calibration circuit comprises:
a duty cycle distortion (DCD) detector circuit to generate a DCD signal based on the first received signal, and the DCD signal indicative of the DCD associated with the first received signal.

16. The transceiver apparatus of claim 15, wherein the second calibration circuit comprises:
a comparator circuit coupled to the DCD detector circuit, the comparator circuit to generate the second calibration signal based on the DCD signal and a reference voltage signal.

17. The transceiver apparatus of claim 11, wherein the FSM circuit is to:
generate one or more pull-up codes and one or more pull-down codes as the one or more activation signals, based on the first calibration signal;
adjust a number of pull-up links of the first Tx driver circuit based on the one or more pull-up codes; and
adjust a number of pull-down links of the first Tx driver circuit based on the one or more pull-down codes.

18. The transceiver apparatus of claim 17, wherein the FSM circuit is to:
generate one or more additional pull-down codes based on the second calibration signal; and
adjust the number of pull-down links of the first Tx driver circuit further based on the one or more additional pull-down codes.

19. The transceiver apparatus of claim 11, further comprising a system on chip (SoC), the SoC including an integrated circuit (IC), the IC including two or more of the first Rx driver circuit, the second Rx driver circuit, the first calibration circuit, the second calibration circuit, and the multiplexer circuit.

20. A method for receiver calibration, the method comprising:
detecting one or more signals at a receiver, the one or more signals generated by a transmit (Tx) driver based on at least one activation signal;
generating a first calibration signal based on amplitude of the one or more signals;
generating a second calibration signal based on duty cycle distortion (DCD) associated with the one or more signals; and
updating the at least one activation signal based on one or both of the first calibration signal and the second calibration signal.
